(19) United States
(12) Patent Application Publication
(10) Pub. No.: US 2022/0342625 A1
(43) Pub. Date: Oct. 27, 2022

(54) DISPLAY MODULE, SCREEN AND METHOD FOR OPERATING A DISPLAY MODULE

(71) Applicant: OSRAM Opto Semiconductors GmbH, Regensburg (DE)

(72) Inventors: Thomas SCHWARZ, Regensburg (DE); Andreas PLÖSSL, Regensburg (DE); Horst VARGA, Lappersdorf (DE); Ralph Peter BERTRAM, Herzogenrath (DE)

(21) Appl. No.: 17/640,434

(22) PCT Filed: Aug. 10, 2020
(86) PCT No.: PCT/EP2020/072419

§ 371 Date: Mar. 4, 2022

(30) Foreign Application Priority Data
Sep. 5, 2019 (DE) 10 2019 123 893.5

(51) Int. Cl. G06F 3/14; G09G 3/32; H02J 50/00; H01L 25/16

(52) U.S. Cl. CPC G06F 3/1446; G09G 3/32; H02J 50/005; H01L 25/167; G09G 2300/08; G09G 2300/0426; H02J 50/05

(57) ABSTRACT

A display module includes a carrier with a front face and a rear face. The display module also includes a pixel array. The pixel array includes a plurality of electrically drivable pixels on the front face. In operation, electromagnetic radiation is emitted via each driven pixel. The display module further includes a wiring layer on the front face, via which the pixels are electrically connected to one another. The display module additionally includes a receiving unit on the front face. The receiving unit is electrically connected with the wiring layer. The receiving unit is configured to wirelessly receive a supply energy for the operation of the display module.

A display module is specified. A screen and a method for operating a display module are also specified.

A task to be solved is to specify a display module that appears to be borderless. Another task to be solved is to specify a screen with such display modules and a method for operating such a display module.

These tasks are solved inter alia by the objects of claims 1 and 13 and by the method of claim 14. Advantageous embodiments and further developments are the subject of the further dependent patent claims.

First, the display module is specified.

According to at least one embodiment, the display module comprises a carrier with a front face and a rear face. The front face and the rear face extend in particular parallel or substantially parallel to each other. For example, the front face and the rear face each comprise an area of at least 25 cm² or at least 100 cm² or at least 2500 cm² or at least 1 m². Alternatively or additionally, the area of each of the front face and the rear face is at most 25 m² or at most 9 m² or at most 1 m². A thickness of the carrier, measured as a distance between the front face and the rear face, is, for example, between 0.05 mm and 5 mm, inclusive.

The carrier is preferably electrically insulating. For example, the carrier comprises a material that is transparent to visible light. For example, the carrier comprises or consists of a dielectric, such as glass or plastic or sapphire. In particular, the carrier may comprise a plastic film and may be formed to be flexible. Preferably, the carrier is continuous and without interruptions. For example, the carrier is formed in one piece. The carrier may be self-supporting. In particular, the carrier forms the stabilizing component of the display module.

According to at least one embodiment, the display module comprises a pixel array of a plurality of electrically drivable pixels on the front face, wherein electromagnetic radiation, in particular visible light, is emitted via each driven pixel during operation of the display module. A pixel that is not driven (a pixel that is turned off) does not emit radiation and appears dark or black to an observer. A pixel is also referred to as an emission zone. The pixels are arranged in particular in a matrix pattern, for example in a rectangular pattern. For example, the pixel array comprises at least 100 or at least 1000 or at least 10000 pixels. Preferably, the pixels are individually and independently controllable.

Each pixel is, for example, square or hexagonal in shape and then preferably comprises an edge length of between 0.1 mm and 50 mm inclusive, in particular between 0.2 mm and 20 mm inclusive, for example of 1 mm. In operation, electromagnetic radiation is emitted over the entire area of the driven pixel or over a sub-region of the area of the pixel.

Each pixel comprises, for example, three subpixels over which light of different colors is emitted during operation. For example, red light is emitted via a first subpixel, blue light is emitted via a second subpixel, and green light is emitted via a third subpixel. The subpixels are preferably also individually and independently controllable.

The individual pixels or subpixels may be implemented in various ways. For example, each pixel and/or each subpixel is associated with an LED chip that intrinsically generates and emits electromagnetic radiation during operation. For example, the LED chips are each based on a III-V compound semiconductor material. Three LED chips each may be uniquely assigned to the pixels for emitting red, green and blue light. Alternatively, each pixel may have only a single LED chip associated with it, pixelated into three subpixels.

The LED chips can comprise an edge length of at least 200 μm or between 50 μm and 200 μm inclusive (mini-LED chip) or an edge length of at most 50 μm (μ-LED chip).

Alternatively, the individual pixels may each be formed by an OLED (organic light-emitting diode). For example, several or all pixels are formed by a common, interconnected OLED layer sequence.

Another possibility is that the pixel array is a liquid crystal display (LCD). Each pixel is then uniquely assigned a segment whose transparency for electromagnetic radiation, in particular for visible light, can be changed by applying voltage. In this case, the display module preferably still comprises a backlight for the liquid crystal display. The backlight may comprise LED chips. The backlight may be arranged on the front face or on the rear face of the carrier.

According to at least one embodiment, the display module comprises a wiring layer on the front face. The pixels are electrically interconnected via the wiring layer. The wiring layer is arranged, for example, between the pixels and the carrier. In particular, the wiring layer comprises a plurality of individual layers stacked on top of each other. For example, the wiring layer comprises one or more dielectric layers, such as SiO₂ layers, and one or more metal layers. The dielectric layers and the metal layers may be arranged alternately. The pixels are electrically connected via the metal layer(s).

According to at least one embodiment, the display module comprises a receiving unit on the front face. The receiving unit is electrically connected with the wiring layer. The receiving unit is arranged, for example, between the pixels and the front face, in particular between the wiring layer and the front face or in the wiring layer.

According to at least one embodiment, the receiving unit is configured to wirelessly receive a supply energy for operating the display module. That is, the receiving unit is configured to be able to wirelessly receive enough power to power all of the electronics of the display module on the front face, including all of the controls and pixels of the display module. Particularly preferably, no additional wired power transmission is necessary or used to power the electronics on the front face. The received supply energy is then, possibly after processing, further transmitted as electrical energy from the receiving unit via the wiring layer to the pixels/to the pixel array and used to drive the pixels.

During operation of the display module, a transmitting unit is used to supply the display module with the supply energy. The transmitting unit transmits the supply energy wirelessly to the receiving unit, and the receiving unit is configured to receive what is transmitted from the transmitting unit. That is, in the intended operation of the display module, the supply energy is transmitted wirelessly from the transmitting unit to the receiving unit. The transmitting unit can be part of the display module, in particular be permanently integrated in the display module, or be an external unit that can be transported separately from the display module, for example.

In at least one embodiment, the display module comprises a carrier with a front face and a rear face, and a pixel array comprising a plurality of electrically controllable pixels on the front face. In operation, electromagnetic radiation is emitted via each driven pixel. The display module further comprises a wiring layer on the front face through which the pixels are electrically interconnected. Further, the display module comprises a receiving unit on the front face, wherein the receiving unit is electrically connected with the wiring layer. The receiving unit is configured to wirelessly receive a power supply for operating the display module.

In particular, the present invention is based on the realization that many video screens nowadays are modular in design to make them transportable, storable, mountable and repairable. To this end, a plurality of display modules are used, each in turn comprising a plurality of pixels. In order to fit them together seamlessly, that is, to keep the pixel pitch constant even in the transition region between two display modules, borderless display modules are desirable. With the present invention, wired power transmission paths at the edges of the display module can be avoided. This eliminates dark appearing lines between the display modules. The display modules appear edge-to-edge, thereby enhancing image quality.

According to at least one embodiment, the display module comprises a transmitting unit on the rear face. The transmitting unit may be arranged directly on the rear face or may be arranged spaced from the rear face.

According to at least one embodiment, the transmitting unit is configured to transmit the supply energy for the operation of the display module through the carrier to the receiving unit. That is, the transmitting unit and the receiving unit are configured for wireless power transmission from the rear face through the carrier to the front face. Particularly preferably, the display module is free of wired power transmission between the rear face and the front face. That is, the front face and the rear face are electrically isolated from each other. Alternatively, for example, at most one ground contact is formed between the front face and the rear face.

In particular, the transmitting unit and the receiving unit are configured such that, given an appropriate power supply to the transmitting unit, enough power can be transmitted wirelessly from the transmitting unit to the receiving unit to power all of the electronics of the display module on the front face, including all of the controls and pixels of the display module. The transmitting unit comprises, for example, a connector, such as a plug or a socket, via which the supply energy or control signals can be supplied to the transmitting unit via cables.

Preferably, when the transmitting unit, the receiving unit and the pixel array are projected onto the front face, both the transmitting unit and the receiving unit overlap with the pixel array. For example, the projections of the transmitting unit and the receiving unit lie entirely within the projection of the pixel array. In an alternative embodiment, the projections of the transmitting unit and the receiving unit lie outside the projection of the pixel array.

According to at least one embodiment, the receiving unit is configured to wirelessly receive control signals or data for individual control of individual pixels. The transmitting unit is then preferably configured accordingly to transmit the control signals wirelessly to the receiving unit. In particular, the transmitting unit is configured to transmit the control signals wirelessly from the rear face through the carrier to the receiving unit. In particular, the control signals comprise information about which pixels are to be controlled. Particularly preferably, no wired signal transmission from the rear face to the front face is necessary or used for the individual control of the individual pixels.

According to at least one embodiment, the receiving unit is configured for inductive, wireless reception of the supply energy. Alternatively or additionally, the receiving unit is configured for capacitive, wireless reception of the supply energy. Further alternatively or additionally, the receiving unit is configured for optical, wireless reception of the supply energy.

The transmitting unit used is configured accordingly for inductive and/or capacitive and/or optical wireless transmission of the supply energy.

Further, the receiving unit/transmitting unit can also be configured for inductive and/or capacitive and/or optical, wireless receiving/transmitting of the control signals.

According to at least one embodiment, the receiving unit comprises one or more coils for inductive wireless reception of the supply energy. Correspondingly, the transmitting unit then preferably also comprises one or more coils for transmitting the supply energy. The coils of the receiving unit are, for example, each a flat coil or a planar coil or a wire-wound coil, for example with a ferrite core. Similarly, the coils of the transmitting unit may each be one of the coils just mentioned. Preferably, the coils of the transmitting unit and the receiving unit are arranged in pairs facing each other. That is, when the coils of the transmitting unit and the receiving unit are projected onto the front face of the carrier, one coil of the transmitting unit overlaps with one coil of the receiving unit, respectively. Preferably, the coils of the transmitting unit and the receiving unit each comprise at least 10 or at least 50 turns. The coils may comprise square windings, hexagonal windings, circular windings, or octagonal windings.

According to at least one embodiment, the receiving unit comprises one or more electrodes for capacitive wireless reception of supply energy. Accordingly, the transmitting unit then preferably also comprises one or more electrodes for transmitting the supply energy. The electrodes of the transmitting unit and the receiving unit are preferably arranged opposite each other. For example, the electrodes are each in direct contact with the carrier. For example, the electrodes are each rectangular in shape.

According to at least one embodiment, for optical, wireless reception of the supply energy, the receiving unit comprises one or more photodetectors. Accordingly, the receiving unit preferably comprises one or more radiation emitting elements for transmitting the supply energy. The radiation emitting elements are, for example, each a laser, for example a semiconductor laser, or an LED. The photodetectors each comprise, for example, amorphous or polycrystalline silicon. In particular, the photodetector or photodetectors are integrated into the wiring layer. The photodetector or photodetectors may each be a photodiode or a photoelement.

According to at least one embodiment, the receiving unit comprises a first receiving element and a second receiving element. The first receiving element is configured to wirelessly receive supply power for the display module. The second receiving element is configured for wirelessly receiving control signals for individually driving individual pixels.

In this case, the transmitting unit preferably comprises a first transmitting element and a second transmitting element. The first transmitting element is configured for wireless transmission of the supply energy and the second transmitting element is configured for wireless transmission of the control signals.

The first transmitting element and the first receiving element preferably form a first pair configured to transmit the supply energy for an operation of the display module. The second transmitting element and the second receiving element preferably form a second pair configured to transmit control signals. The display module may comprise a plurality of such first and/or second receiving elements or pairs. All features disclosed for a receiving element or pair of transmitting element and receiving element are also disclosed for all further receiving elements or pairs of transmitting element and receiving element, respectively.

Preferably, the display module comprises a plurality of second receiving elements or second pairs each comprising a second transmitting element and a second receiving element. Each second receiving element or second pair is then associated with, for example, a different type of control signal. For example, a second receiving element or second pair has associated therewith the control signals for red subpixels, another second receiving element or second pair has associated therewith the control signals for green subpixels, another second receiving element or second pair has associated therewith the control signals for blue subpixels, another second receiving element or second pair has associated therewith the control signals for synchronization, and so forth.

The transmitting and receiving elements may each comprise or consist of a coil or pair of electrodes or a radiation emitting element and a photodetector, respectively. The transmitting and receiving elements of a pair preferably overlap with each other when projected on the front face, particularly if they are coils or electrodes. The dimensions and/or winding numbers of the coils of the first transmitting element and/or the first receiving element are preferably selected to be larger than the coils of the second transmitting element and the second receiving element.

As an alternative to the use of separate transmitting and receiving elements for the transmission of supply energy and for the transmission of control signals, however, it is also possible for a pair comprising a transmitting element and a receiving element to be configured both for the transmission of supply energy and for the transmission of control signals. For example, the supply energy is transmitted on a carrier frequency of approximately 1 MHz. The control signals are transmitted with the aid of frequency modulation, for example. In this case, the display module comprises, for example, only a single receiving element or a single pair of transmitting element and receiving element.

The pixels of the display module may be divided into a plurality of pixel groups each comprising a plurality of pixels. Each pixel group may have a receiving element or a pair of transmitting element and receiving element uniquely associated therewith. For example, a second receiving element or second pair is uniquely associated with each pixel group for transmitting control signals for the pixel group.

The display module may comprise a single first receiving element or a single first pair of first transmitting element and first receiving element with which to receive/transmit supply power for operation of all front face electronics. Alternatively, multiple first receiving elements or first pairs, each comprising a first transmitting element and a first receiving element, may be used to receive/transmit the power necessary to operate all of the electronics on the front face of the display module.

According to at least one embodiment, the wiring layer and/or the receiving unit are thin-film structures. For example, the wiring layer and/or the receiving element are produced by a thin-film technique, such as sputtering or CVD or PVD. For example, the thickness of the wiring layer, measured perpendicular to the front face, is at most 20 μm or at most 10 μm or at most 5 μm. For example, the thickness of the receiving unit, in particular the receiving elements or coil(s) or electrode(s), is at most 3 μm or at most 1 μm, for example 0.5 μm.

According to at least one embodiment, the display module comprises an active-matrix control system on the front face for individual control of the individual pixels. For example, the active-matrix control system implements cross-matrix control or daisy-chain control of the pixels.

For example, the active-matrix control system includes a row driver and a column driver for driving the pixels. The column driver comprises, for example, shift registers, memories, voltage converters, digital-to-analog (DA) converters, and buffers. For example, the row driver comprises voltage converters, buffers, and shift registers to parallelize a serial data/signal stream.

Preferably, the active matrix control system comprises a plurality of transistors, wherein at least one transistor is uniquely associated with each pixel. The transistors are used to drive, i.e., turn on and off, the pixels. With the aid of the column drivers and row drivers, for example, the transistors assigned to the pixels are programmed or switched in accordance with the intended control for the pixel.

According to at least one embodiment, the wiring layer comprises thin-film transistors. In particular, the wiring layer is a so-called TFT layer. In this case, in addition to the dielectric layers and the metal layers, the wiring layer preferably also comprises one or more semiconductor layers, for example of amorphous silicon or polycrystalline silicon. Each pixel is preferably uniquely assigned at least one of the thin-film transistors of the wiring layer. The thin-film transistors form, for example, the transistors of the active-matrix control system assigned to the pixels.

In addition to the transistors, other circuits for controlling the pixels may also be integrated in the wiring layer. For example, control elements of the active-matrix control system, such as the row driver and/or the column driver, are integrated in the wiring layer. Further, circuits for power supply and data processing may be integrated in the wiring layer.

According to at least one embodiment, the display module comprises semiconductor chips, in particular IC chips (IC=integrated circuit), on the front face. The semiconductor chips are each arranged in the region between two pixels. The semiconductor chips are configured to control the pixels.

The semiconductor chips preferably each comprise edge lengths of at most 200 μm or at most 100 μm or at most 50 μm and thicknesses of at most 50 μm or at most 20 μm. In plan view, the semiconductor chips preferably do not overlap with the radiation emitting surfaces of the pixels.

For example, the line driver and/or the column driver of the display module each comprise at least one of the semiconductor chips. Further, one or more of the semiconductor chips may be configured for data processing and power supply. In this case, for example, only the (thin-film) transistors associated with the individual pixels are integrated in the wiring layer.

Preferably, when the semiconductor chips are arranged in the region between the pixels, the radiation emitting area of the pixels is smaller in each case, for example less than or equal to 50%, of the total area of the pixel. This is particularly the case if a mini-LED chip or a μ-LED chip is assigned to each of the pixels. The edge length of the semiconductor chips is, for example, at most one fifth or at most one tenth of the edge length of the pixels.

By arranging the semiconductor chips used for controlling the pixels in the region between the pixels, it is avoided that the edge of the display module is widened by an arrangement of control electronics. In this way, display modules that appear borderless can again be created. Preferably, then, as viewed from the front face in a plan view, each semiconductor chip is spaced from the edge of the display module by at least a portion of an area of a pixel that emits radiation during operation.

The semiconductor chips may further comprise the transistors for the individual pixels. In this case, for example, the wiring layer does not comprise thin-film transistors.

Preferably, the semiconductor chips in this case are so-called μIC chips, each with edge lengths of at most 50 μm and thicknesses of at most 20 μm. Such μIC chips can be easily mounted between the pixels. μ-IC chips are also particularly suitable if the pixels are implemented by OLEDs, since they cover only a small part of the radiation emitting area of the pixels.

Next, the screen is specified. The screen comprises several of the display modules described here. The display modules are interconnected. For example, the display modules are connected to each other by a frame. In particular, the display modules are arranged side by side in a direction parallel to the front face of the display modules. The screen comprises, for example, at least 16 or at least 100 of the display modules described herein. The screen is in particular a video screen.

Next, the method for operating a display module is specified. With the method, a display module described herein is operated. All features disclosed in connection with the method are therefore also disclosed for the display module, and vice versa.

According to at least one embodiment, the method first executes a step A) in which control signals for individually driving individual pixels and a supply energy for operating the display module are wirelessly transmitted from a transmitting unit through the carrier to the receiving unit. In a step B), the control signals and the supply energy are transmitted from the receiving unit to the pixels via the wiring layer. In a step C), the individual pixels are driven in response to the control signals and with the aid of the supply energy, wherein electromagnetic radiation is then emitted via the driven pixels.

Steps A) to C) are carried out in alphabetical order. Preferably, no wire connection from the rear face to the front face is used for power transfer during operation of the display module. Particularly preferably, during operation the display module is supplied exclusively wirelessly with supply energy and control signals/data.

The energy to be transmitted (control signals and supply energy) are preferably modulated by modulation techniques, for example frequency modulated. The electronics on the front face, in particular the semiconductor chips, preferably include filters, for example bandpass filters, to filter out the desired signals. In this way, transmission reliability can be ensured.

Further advantageous embodiments and further embodiments of the display module, the screen and the method for operating a display module are apparent from the exemplary embodiments described below in conjunction with the figures. Elements that are the same, similar or have the same effect are provided with the same reference signs in the figures. The figures and the proportions of the elements shown in the figures are not to be regarded as to scale. Rather, individual elements, in particular layer thicknesses, may be shown exaggeratedly large for better illustration and/or understanding.

Showing in:

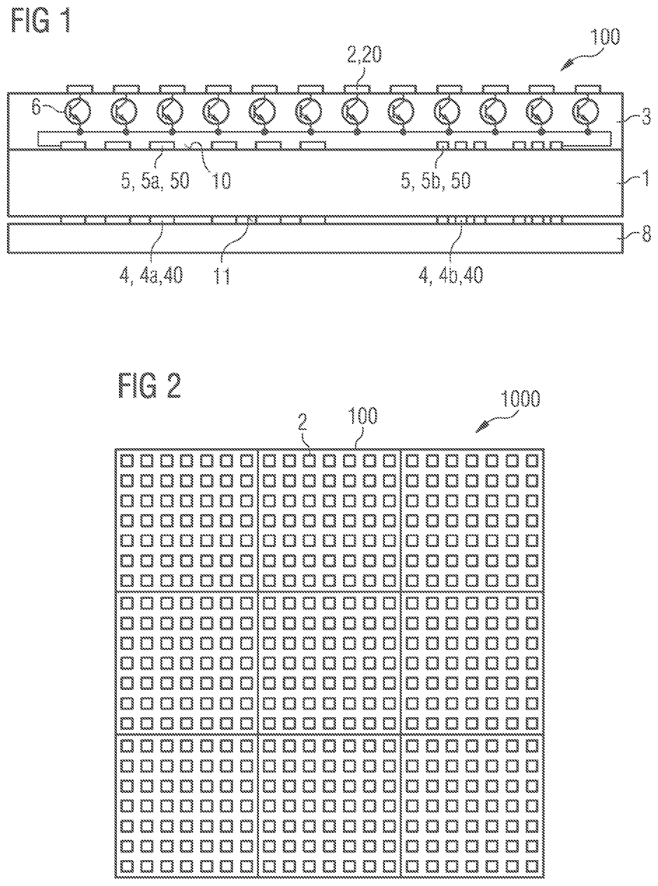

FIGS. 1, 6 and 8 to 11 exemplary embodiments of the display module, each in cross-sectional view,

FIG. 2 an exemplary embodiment of the screen in plan view,

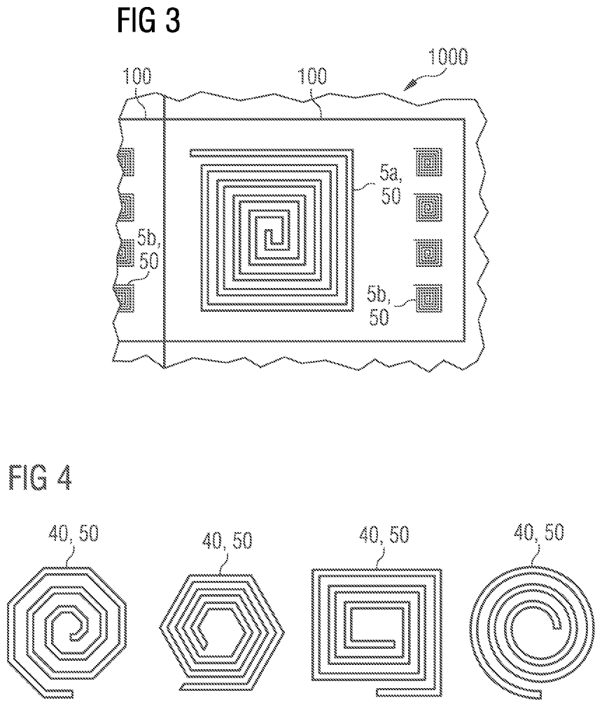

FIGS. 3 and 5 sections of an exemplary embodiment of the screen in various sectional views,

FIG. 4 various exemplary embodiments of coils,

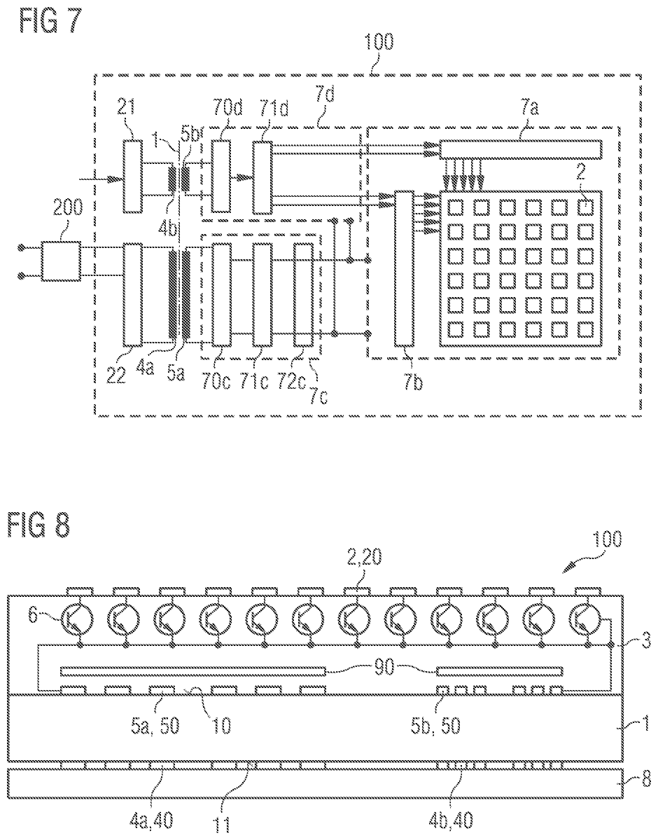

FIG. 7 a schematic switching arrangement of an exemplary embodiment of the display module.

FIG. 1 shows a first exemplary embodiment of the display module 100 in cross-sectional view. The display module 100 comprises a carrier 1, for example made of plastic or glass. The carrier 1 comprises a front face 10 and a rear face 11 opposite the front face 10. Areas of the front face 10 and the rear face 11 are, for example, in the region between 100 cm² and 9 m² inclusive.

A wiring layer 3 and a pixel array comprising a plurality of pixels 2 are arranged on the front face 10 of the carrier 1. In the present case, the pixels 2 are each formed by an LED chip 20. The individual pixels 2 are electrically connected to each other via the wiring layer 3. In particular, a plurality of thin-film transistors 6 are integrated in the wiring layer 3, wherein each thin-film transistor 6 is uniquely assigned to a pixel 2. The associated pixels 2 can be switched on and off via the thin-film transistors 6. The wiring layer 3 includes, for example, a plurality of layers formed by a thin-film technique, such as a metal layer, a dielectric layer and a semiconductor layer, whereby the individual thin-film transistors 6 and the interconnection between the pixels 2 are realized.

On the front face 10 between the wiring layer 3 and the carrier 1, a receiving unit 5 comprising a first receiving element 5a in the form of a coil 50 and a second receiving element 5b in the form of another coil 50 is arranged. A transmitting unit 4 comprising a first transmitting element 4a in the form of a coil 40 and a second transmitting element 4b in the form of a further coil 40 is arranged on the rear face 11. The first transmitting element 4a is opposite the first receiving element 5a. The second transmitting element 4b is opposite the second receiving element 5b. The coils 40 may be arranged directly on the rear face 11. However, in the present exemplary embodiment, the coils 40 are arranged on an auxiliary carrier 8 and not directly on the carrier 1. For example, the coils 40 are spaced somewhat from the carrier 1. In particular, the transmitting unit 4 is not part of the display module 100 here and is preferably transportable independently of the display module 100. However, the reverse case, in which the transmitting unit 4 is part of the display module 100 and then cannot be detached from the display module 100 in a non-destructive manner, for example, is also conceivable. The coils 40, 50 are each produced in the present case, for example, by a thin-film technique.

In operation of the display module 100, a supply energy for operating the display module 100 is transmitted to the first receiving element 5a via the first transmitting element 4a. From there, the supply energy is transmitted via the wiring layer 3 to the electronics on the front face 10. Control signals or data are transmitted wirelessly to the second receiving element 5b via the second transmitting element 4b. The control signals store which pixels 2 are to be controlled in which way. The pixels 2 are then controlled in dependence on these control signals and with the aid of the supply energy.

In FIG. 2, an exemplary embodiment of a screen 1000 is shown in plan view. The screen 1000 comprises a plurality of display modules 100, for example, a plurality of the display modules 100 of FIG. 1. The display modules 100 are interconnected and arranged side by side in a direction parallel to the front face. The screen 1000 forms a video screen, for example.

In FIG. 3, a portion of an exemplary embodiment of the screen 1000 is shown. More specifically, FIG. 3 shows a display module 100 of the screen 1000 and parts of the adjacent display modules 100. In FIG. 3, only the plane in which the receiving elements 5a, 5b are arranged is shown. As can be seen, a first receiving element 5a in the form of a large coil 50 and a plurality of second receiving elements 5b each in the form of a smaller coil 50 are associated with the display module 100. For example, in the present exemplary embodiment, the pixels 2 are divided into four pixel groups, wherein a second receiving element 5b (and the corresponding second transmitting element 4b) is associated with each pixel group. The first receiving element 5a supplies all of the pixel groups and all of the remaining electronics on the front face of the display module 100 with sufficient supply power for operation.

FIG. 4 shows several exemplary embodiments of coils 40, 50 with different geometries. The coils 40, 50 are each flat coils with thin, metallic conductor paths. The thickness of the conductor paths is, for example, at most 500 nm. The coils 40, 50 of FIG. 4 differ in their geometry. The coils 40, 50 comprise, for example, 150 turns each. The widths of the conductor paths of the coils 40, 50 are, for example, around 30 μm. The spacing of the conductor paths between two adjacent windings is also 30 μm, for example. An outer diameter of the coils 40, 50 is then approximately 20 mm in each case, for example, and an inner diameter of the coils 40, 50 is approximately 2 mm in each case, for example. With such coils 40, 50, an inductance of approximately 200 μH is achieved. The square coil 40, 50 achieves particularly high inductances because it encloses the largest area. The coils 40, 50 of FIG. 4 with the specified dimensions are particularly suitable for use in a first transmitting element and first receiving element which is configured to transmit the supply energy.

Instead of one first receiving element 5a and one first transmitting element 4a per display module 100 each in the form of a single coil (see FIG. 3), it may be advantageous to use several first receiving elements 5a and correspondingly several first transmitting elements 4a each in the form of a coil 40, 50 per display module 100. For example, with a module size of 80 mm×90 mm and a pixel edge length of 1 mm, one would have a power requirement per display module 100 of 6 W at a luminance of 2000 cd/m2. The current requirement per display module 100 would then be approximately 1.5 A. With a coil thickness of about 0.3 μm, this would be a relatively large current. In this case, for example, nine first receiving elements 5a and corresponding first transmitting elements 4a would be useful. Each coil 40, 50 would then have to carry only 0.17 A. A coil edge length could be approximately 25 mm. With a width of the conductor paths of the coils of approximately 300 μm, a pitch between adjacent conductor paths of 400 μm and 31 turns per coil, the heating of the coils would be less than 20° C.

FIG. 5 again shows the section of the screen 1000 in which a display module 100 is shown in detail. However, unlike in FIG. 3, the plane in which the pixels 2 are arranged is now shown. As can be seen in the present exemplary embodiment, each pixel 2 is associated with a μLED chip 20. The areas of the pixels 2 are each larger than the areas of the μLED chips 20 by at least a factor of 5. As a result, the region between two adjacent pixels that is not illuminated during operation is relatively large. This in turn allows semiconductor chips 7a, 7b, 7c, 7d for controlling the pixels 2 to be arranged between the pixels 2 without affecting the image quality.

In the present exemplary embodiment, the display module 100 comprises an active-matrix control system. The active-matrix control system comprises a column driver comprising two semiconductor chips 7a, and a row driver comprising two other semiconductor chips 7b. In addition, the display module 100 includes a semiconductor chip 7d for data processing and a semiconductor chip 7c for power supply. The functions of the semiconductor chips 7b, 7d will be further explained in connection with FIG. 7.

An advantage of arranging the semiconductor chips 7a, 7b, 7c, 7d in the region between the pixels 2 is that this eliminates the need to arrange semiconductor chips for controlling the pixels at the edges of the display module 100, making the display module 100 appear to have no edges in operation.

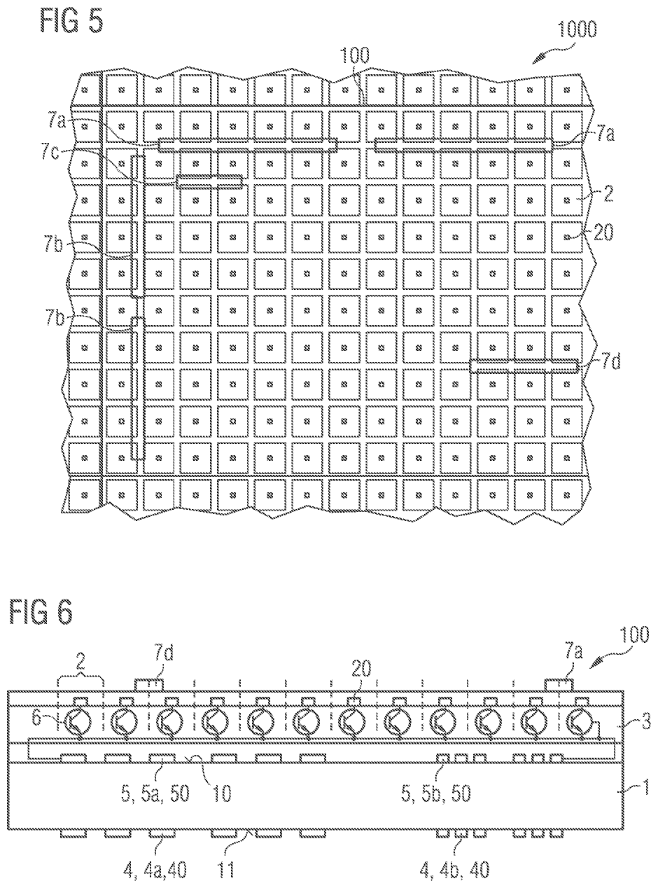

FIG. 6 shows a cross-sectional view of the display module 100 shown in FIG. 5. The dashed lines indicate the boundaries between adjacent pixels 2. It can be seen that the semiconductor chips 7a, 7d are each arranged in the region between two pixels 2, in particular in the region between the LED chips 20 of two adjacent pixels 2. Furthermore, the semiconductor chips 7a, 7d are arranged here in a different plane than the LED chips 20. However, it is equally conceivable that the semiconductor chips 7a, 7d are arranged in the same plane as the LED chips 20.

In FIG. 7, a schematic switching arrangement of an exemplary embodiment of the display module 100 is shown. For example, it is the switching arrangement of the exemplary embodiment of FIGS. 3 and 5.

Image data and control signals, respectively, are present in the form of high-frequency signals. The control signals can still be modulated to increase the transmission reliability. They are forwarded to the second transmitting element 4b on the rear face of the carrier 1 via an impedance converter 21. From there, the control signals are forwarded wirelessly through the carrier 1 to the front face of the carrier to the second receiving element 5b. From the second receiving element 5b, the control signals are then forwarded to the semiconductor chip 7d, which is configured for data processing of the control signals. In particular, the semiconductor chip 7d comprises an impedance converter 70d and a demultiplexer 71d. The semiconductor chip 7d is signal-connected with the semiconductor chips 7a of the column driver and the semiconductor chips 7b of the row driver. Thus, the processed control signals are passed to the column driver and the row driver, which are then used to drive the individual pixels 2 in response to the control signals.

Supply power for the display module 100 is provided by a power supply 200. A modulator 22 at the rear face of the carrier 1 modulates the voltage and this is applied to the first transmitting element 4a at the rear face of the carrier 1. The supply energy is then transmitted wirelessly through the carrier 1 to the first receiving element 5a. From the first receiving element 5a, the supply energy is transmitted through the wiring layer 3 to the semiconductor chip 7c for supplying the voltage. This semiconductor chip 7c includes a circuit 70c for rectifying the electric voltage/current, a circuit 71c for smoothing, and a circuit 72c for stabilizing. For example, capacitors are used for smoothing.

Alternatively, the capacitors for smoothing may be integrated in the wiring layer. The pixel array is then supplied with power via the semiconductor chip 7c.

FIG. 8 shows another exemplary embodiment of the display module 100. The exemplary embodiment of FIG. 8 is similar to that of FIG. 1. Unlike FIG. 1, in the exemplary embodiment of FIG. 8, core plates 90, for example made of nickel or cobalt or iron, are arranged in a plane above the coils 50 of the first 5a and second 5b receiving elements. The core plates 90 overlap in a projection on the front face with the coils 50. The core plates 90 guide the magnetic field and thereby reduce losses.

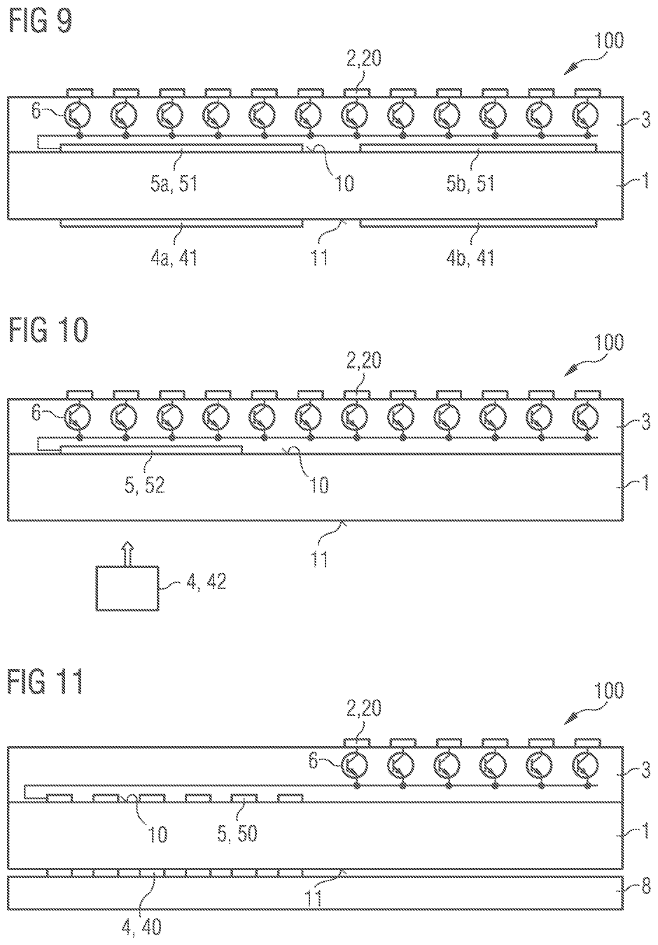

In FIG. 9, another exemplary embodiment of the display module 100 is shown in a cross-sectional view. Unlike in the exemplary embodiment of FIG. 1, the transmitting unit 4 and the receiving unit 5 comprise electrodes 41, 51 rather than coils. The wireless energy transmission for the supply energy and the control signals is capacitive here. The electrodes 41, 51 are each preferably applied directly to the carrier 1 here.

In FIG. 10, an exemplary embodiment of the display module 100 is shown in cross-sectional view, wherein the transmitting unit 4 comprises a radiation emitting element 42, such as a semiconductor laser. The receiving unit 5 comprises a photodetector 52. The photodetector 52 may be produced using thin-film technology and may be based on amorphous silicon, for example. In operation, the radiation emitting element 42 transmits both the supply energy and the control signals to the photodetector 52. That is, the transmission of supply energy and control signals is realized in a single pair of transmitting element and receiving element.

FIG. 11 shows another exemplary embodiment of the display module 100. For example, the receiving unit 5 and the transmitting unit 4 each comprise only a single coil 40, 50 through which both the supply energy and the control signals are transmitted wirelessly. In the preceding exemplary embodiments, the transmitting unit 4 and the receiving unit 5 were each arranged overlapping, in particular completely overlapping, with the pixel array of pixels 2. In the exemplary embodiment of FIG. 11, this is not the case. Here, the projections of the transmitting unit 4 and the receiving unit 5 onto the front face 10 lie outside the corresponding projection of the pixel field.

The invention is not limited to the exemplary embodiments by the description based thereon. Rather, the invention encompasses any new feature as well as any combination of features, which particularly includes any combination of features in the patent claims, even if that feature or combination itself is not explicitly specified in the patent claims or exemplary embodiments.

This patent application claims priority to German patent application 102019123893.5, the disclosure content of which is hereby incorporated by reference.

### LIST OF REFERENCE SIGNS

1 carrier
2 pixel
3 wiring layer
4 transmitting element
4a first transmitting element
4b second transmitting element
5 receiving element
5a first receiving element
5b second receiving element
6 thin-film transistor
7a, 7b, 7c, 7d semiconductor chip
8 auxiliary carrier
10 front face
11 rear face
20 LED chip
21 impedance converter
22 modulator
40, 50 coil
41, 52 electrode
42 radiation emitting element
52 photodetector
70d impedance converter
71d demultiplexer
70c, 71c, 72c circuit
90 core plate
100 display module
200 power supply
1000 screen

1. A display module comprising
a carrier with a front face and a rear face,
a pixel array comprising a plurality of electrically drivable pixels on the front face wherein, in operation, electromagnetic radiation is emitted via each driven pixel,
a wiring layer on the front face, via which the pixels are electrically connected to one another, and
a receiving unit on the front face, wherein
the receiving unit is electrically connected with the wiring layer, and
the receiving unit is configured to wirelessly receive a supply energy for the operation of the display module.

2. The display module according to claim 1, further comprising
a transmitting unit at the rear face, wherein
the transmitting unit is configured to transmit the supply energy for the operation of the display module through the carrier to the receiving unit.

3. The display module according to claim 1,
wherein the receiving unit is configured to wirelessly receive control signals for individually driving individual pixels.

4. The display module according to claim 1,
wherein the receiving unit is configured for inductive and/or capacitive and/or optical wireless reception of supply energy.

5. The display module according to claim 1,
wherein the receiving unit comprises at least one coil for inductive, wireless receiving of the supply energy.

6. The display module according to claim 1,
wherein the receiving unit comprises at least one electrode for capacitive, wireless reception of the supply energy.

7. The display module according to claim 1,
wherein for optical, wireless receiving of the supply energy, the receiving unit comprises at least one photodetector.

8. The display module according to claim 1, wherein
the receiving unit comprises a first receiving element and a second receiving element,
the first receiving element is configured for wireless reception of the supply power for the display module, and
the second receiving element is configured for wireless reception of control signals for the individual control of individual pixels.

9. The display module according to claim 1,
wherein the wiring layer and/or the receiving unit are thin-film structures.

10. The display module according to claim 1,
comprising an active matrix control system on the front face for individually driving the individual pixels.

11. The display module according to claim 10, wherein
the wiring layer comprises thin-film transistors, and
at least one thin-film transistor is assigned to each pixel for controlling the pixel.

12. The display module according to claim 10, wherein
the display module comprises semiconductor chips on the front face
the semiconductor chips are each arranged in the region between two pixels, and
the semiconductor chips are configured to control the pixels.

13. A screen comprising a plurality of interconnected display modules each according to claim 1.

14. A method for operating a display module according to claim 1, comprising
A) Wirelessly transmitting control signals for individually driving individual pixels and supply power for operating the display module from a transmitting unit through the carrier to the receiving unit,
B) Forwarding the control signals and the supply energy from the receiving unit to the pixels via the wiring layer, and
C) Driving individual pixels as a function of the control signals and with the aid of the supply energy, wherein electromagnetic radiation is emitted via the driven pixels.

15. The method for operating a display module according to claim 14,
wherein steps A) to C) are carried out in alphabetical order.

16. The method for operating a display module according to claim 14,
wherein the control signals and/or the supply energy are frequency modulated.

17. A display module comprising
a carrier with a front face and a rear face,
a pixel array comprising a plurality of electrically drivable pixels on the front face, wherein, in operation, electromagnetic radiation is emitted via each driven pixel,
a wiring layer on the front face, via which the pixels are electrically connected to one another, and
a receiving unit on the front face,
wherein
the receiving unit is electrically connected with the wiring layer,
the receiving unit is configured to wirelessly receive a supply energy for the operation of the display module,
the wiring layer is arranged between the pixels and the carrier, and
the receiving unit is arranged between the pixels and the front face.
